(19) United States
(12) Patent Application Publication
(10) Pub. No.: US 2014/0345482 A1
(43) Pub. Date: Nov. 27, 2014

(54) PRINTING FORM FOR USE IN RELIEF PRINTING, IN PARTICULAR FLEXOGRAPHIC PRINTING

(71) Applicant: ContiTech Elastomer-Beschichtungen GmbH, Hannover (DE)

(72) Inventors: Stefan Fuellgraf, Duderstadt (DE); Armin Senne, Ettenheim (DE)

(73) Assignee: ContiTech Elastomer-Beschichtungen GmbH, Hannover (DE)

(21) Appl. No.: 14/220,043

(22) Filed: Mar. 19, 2014

Related U.S. Application Data
(63) Continuation of application No. PCT/EP2012/066296, filed on Aug. 22, 2012.
(60) Provisional application No. 61/536,343, filed on Sep. 19, 2011.

(30) Foreign Application Priority Data
Sep. 19, 2011 (DE) 10 2011 053 747.3

(51) Int. Cl. B41N 6/00; B41M 1/04; G03F 7/00; B41N 1/22

(52) U.S. Cl. CPC B41N 6/00; B41N 1/22; B41M 1/04; G03F 7/0002
USPC 101/401.1; 451/64; 425/174.4

(57) ABSTRACT

A printing form is for use in relief printing, in particular flexographic printing. The printing form is configured as a single or multilayered cylindrical layer structure having at least a first layer having a vulcanizate based on at least one elastomer. The first layer is extruded.

### CROSS REFERENCE TO RELATED APPLICATIONS

This application is a continuation application of international patent application PCT/EP2012/066296, filed Aug. 22, 2012 which designates the United States and claims priority from U.S. Provisional Application No. 61/536,343 filed Sep. 19, 2011, and German patent application 10 2011 053 747.3 filed Sep. 19, 2011. The present continuation application claims priority to each of the above applications and incorporates herein the entire contents thereof by reference.

### FIELD OF THE INVENTION

The invention relates to a printing form for use in relief printing, in particular flexographic printing, which is configured as a single-layered or multilayered cylindrical layer structure, having at least one first layer which has a vulcanizate based on at least one elastomer.

### BACKGROUND OF THE INVENTION

Printing technology is concerned with the reprography of printing templates, whereby printing inks are transferred from a printing form onto a print substrate, such as, for example paper, cardboard or plastic. A sector of this technology is relief printing, in which the printing elements stand proud of the depressions in the printing form, that is the image sites of the printing form are higher than the non-image sites. The printing elements or image sites, which are configured so as to be elevated, are provided with the printing ink, on account of which they configure the printing template which can then be transferred onto the print substrate in order to reproduce the printing template there.

The printing form can be a single-layered or multilayered cylindrical layer structure with or made from an elastomeric material, which effects the indirect image transfer, for example in offset printing, or the direct image transfer, for example in flexographic printing. The cylindrical layer structure has, as the topmost layer, a printing layer which is oriented toward the print substrate. The printing layer may be provided on a reinforcement layer. In the event that the printing layer and, if applicable, the reinforcement layer are configured so as to be flexible, for example on account of photopolymers, one refers to the flexographic-printing method. In the relief-printing method, further layers between the printing layer and the optional reinforcement layer, for example in the form of a compressible layer, are possible. A plurality of compressible layers and reinforcement layers, which are preferably arranged in an alternating manner, may also be provided. In the conventional manner, all layers form an adhesive bond with one another, that is the mutually adjacent layers are adhesively, that is integrally, connected to one another by, for example, adhesives or by vulcanization.

The configuration of the elevated printing elements or the image sites of the printing template, in the case of the relief-printing method and particularly the flexographic printing method, may take place by means of laser engraving. To this end, the printing layer has photopolymers. Photopolymers are understood to be light-curing polymers, such as, for example, epoxy resins. Alternatively, the elevated printing elements or image sites may also be generated on the printing layer by mechanical machining, for example via milling.

To carry out printing, the cylindrical layer structure may be mounted as a printing form on a printing cylinder in order to continuously transfer, by means of the elevated printing elements or image sites, printing ink onto the print substrate. Arrangements of this type are also referred to as sleeve, printing sleeve, or carrier sleeve, and are used for manufacturing continuous motives, such as for example wallpaper, table napkins or gift wrapping paper.

The manufacture of such multilayered cylindrical layer structures as a printing form takes place in such a manner that no seam or similar is configured on the surface, that is the printing layer. It is, accordingly, customary to date to construct a cylindrical printing form on a non-expandable, or only slightly expandable, strength carrier, such as for example a GRP (glass-fiber reinforced plastic) body, by winding or wrapping elastomeric layers or webs, and to subsequently vulcanize it. Nickel cylinders or steel cylinders may also be used as rigid basic bodies on which, as strength carriers, to construct the elastomeric printing layer.

On account of production-related unevenness and varying layer thicknesses of the elastomeric material in the radial direction, it is necessary here to render the vulcanized cylindrical printing form to the desired layer thickness and surface quality by means of for example grinding. Finally, the sleeve, that is the strength carrier having a vulcanized cylindrical printing form, can be cut to the desired length and shipped. Subsequently, at the engraver's, the sleeve can be clamped in a corresponding device and the printing template (print relief, deep engraving) can be carved out by removal of the depressions or non-image sites. This removal may take place, for example, by laser or a milling tool.

For application in the printing works, the sleeve is pushed onto the printing cylinder and retained there. This may take place by means of mechanical clamping elements, adhesives, suction technology, or magnetic force. It is important here that the sleeve cannot detach itself, even at high rotational speeds, in the radial or axial direction from the printing cylinder and securely maintains its positioning on the printing cylinder.

It is disadvantageous in the manufacturing of sleeves, as is customary to date, that the printing layer, after removal for configuring the elevated printing elements or image sites, can only be used for the reproduction of precisely this one printing template. Once another printing template is to be illustrated, the printing form used to date becomes useless, and with it also the corresponding strength carrier, since, on account of its vulcanized wound construction, it cannot, or only with a large outlay, be separated again from the printing layer. Accordingly, a new strength carrier is required in each case for producing a new printing template, according to the previously described known manufacture, on which new strength carrier a new printing form is then constructed, and subsequently the new printing template is then manufactured on the latter.

It is also disadvantageous that the previously described known manufacture involves very many steps, of which many have to be carried out manually, that is cannot be automated at all or only to a slight degree. In the previously described known manufacture, particularly in countries with high labor rates, this leads to significant costs, which are reflected in the correspondingly high prices of the sleeves.

It is furthermore disadvantageous that, in comparison to the sleeve itself, the sleeve as a finished product of the previously described known manufacture always constitutes a rigid body having a large hollow volume, which is enclosed by the cylindrical strength carrier. Therefore, a much larger volume than occupied by the sleeve itself is necessary for storage and for shipping.

### SUMMARY OF THE INVENTION

It is an object of the invention to provide a printing form of the type described above, such that at least the known disadvantages are overcome, in particular to provide a printing form which can be manufactured and handled independently from a reinforcement member and can be manufactured in a more cost-efficient manner than previously known.

The object is achieved a printing form for use in relief printing, in particular flexographic printing, which is configured as a single-layered or multilayered cylindrical layer structure, having at least one first layer which has a vulcanizate based on at least one elastomer, wherein the first layer is extruded.

Here, the term “extrusion” is understood to be extrusion in the sense of process technology. Plastics or other viscous materials that can be cured, such as for example elastomers (for example natural rubber, rubber) are pressed here in a continuous process through a specially shaped nozzle. Bodies having the cross section of the nozzle and having any desired length are created. It is possible to manufacture, for example, seamless plates, pipes, tubes and profiles having a cross section which is constant throughout the length by extrusion. For example, an extruded tube is enclosed by a mold and blown against the wall of the tool by means of compressed air. In this case, one refers to extrusion blow molding.

The invention is based on the findings that a printing form for relief printing, in particular flexographic printing, is conventionally manufactured in a comparatively complex manner, as a single-layered or multilayered cylindrical layer structure, for this purpose in that they are substantially made of an elastomeric or elastomer-containing layer, as is customary in tubes. According to the invention, a printing form is thus manufactured like an extruded tube. On account thereof, the methods known and tested for manufacturing tubes can be utilized in order to in this manner manufacture an elastomeric or elastomer-containing printing form more simply and more cost-effectively than is customary to date. In this manner, the printing form according to the invention can be manufactured, handled, stored, shipped and used as an elastic tube, independently from the strength carrier customarily used to date, which serves inter alia as a base in manufacturing during winding or wrapping. The term “tube” in the sense of the present invention is understood to mean a flexible conduit for conveying solid, liquid and gaseous materials. In contrast to a rigid pipe, a conduit is configured so as to be flexible, that is bendable.

Preferably, an elastomeric material, which is manufactured and marketed by the company Gummiwerk Kraiburg GmbH & Co. KG under the product code AA6FIZ, is used for manufacturing the first extruded layer.

It is advantageous here that the extrusion of tubes is a method which is established, tested, known and widely used. In this manner, available production facilities can be used, without or with only modest outlay for modifications, for producing a printing form as a single-layered or multilayered cylindrical layer structure having the method steps of tube manufacturing. This leads to low manufacturing costs and also to high product quality, since it is possible to build upon already acquired experience in tube manufacturing.

It is furthermore particularly advantageous that tube manufacturing is a largely automated manufacturing method, in contrast to the known wound and wrapped construction of the printing form on a strength carrier, which requires numerous manual steps. It is also for this reason that the manufacturing costs for a printing form can be reduced according to the invention.

It is particularly advantageous here that the elastic printing form, when required, can be readily mounted on a reinforcement member and also readily removed again from the reinforcement member, for example by expansion by means of compressed air from the inside, or by suction by means of a vacuum from the outside, in order to form a sleeve. In the same manner, this connection between the elastic printing form and the reinforcement member can be readily established and also repealed again, such that the same reinforcement member can be provided with a new elastic printing form and reused. This is not possible in the case of the conventionally wound or wrapped construction of the sleeve, the a connection which is permanent and not releasable in a non-destructive manner is established here between the reinforcement member, which is required for manufacturing, and the wound or wrapped elastomeric printing layer.

Regardless of whether the elastic printing form is used on its own or on a reinforcement member, in either case the elastic printing form can be readily mounted on a printing cylinder, or similar, for utilization in a printing method.

It is also particularly advantageous here that the elastic printing form can be handled, stored and shipped without the use of a reinforcement member. In this manner, the elastic printing form represents a cylindrical body which can be folded or collapsed in order to reduce its volume and, on account thereof, to save storage space or shipping space. On account of its elastic properties, the elastic printing form can, however, expand back to its cylindrical shape without any damage having occurred to its shape or surface as a result of folding or collapsing. This simplifies and facilitates handling, storage and shipping of a printing form according to the invention.

According to one aspect of the invention, the printing form has a further layer, which is configured as a reinforcement layer.

It is advantageous here that this reinforcement layer enhances the stability of the printing form and, on account thereof, makes the printing form more resilient, more robust and simpler to handle. The reinforcement layer here may have one type of reinforcement member or a plurality of different types of reinforcement members, such as one or more textile formations, for example knits, warp knits, or weaves of identical construction or of different constructions. These may, for example, be embedded in a polymer material, preferably in a vulcanized polymer material, that is surrounded by the latter, or have such a polymer material in relation to the first layer. A film, for example a polymer film (for example a polyamide film), or a metal foil, may also be applied as a reinforcement layer. In a printing form having many layers and at least two reinforcement layers, a combination of one textile formation and one film/foil or one film composite/foil composite may also be implemented.

It is preferable here if the first layer and the reinforcement layer merge with one another, or if the reinforcement layer is configured as part-region of the first layer. This may be achieved in that, in extrusion, the first layer is extruded onto the reinforcement layer and the first layer, prior to vulcanization, penetrates the reinforcement layer such that, after vulcanization, at least one part-region, preferably the part-region of the first layer which, in the radial direction R, faces the inside of the printing form, is permeated by the reinforcement layer.

According to a further aspect of the invention, the printing form has a further layer, which is configured as a compressible layer.

This is advantageous, since in this manner the compressible layer—also referred to as the compression layer—serves to avoid a fulling process, by reducing the volume in the printing zone, and to compensate for differences in the indentation. It is critical in the compressible layer that it does not expand when compressed, that is that its volume, when compressed, is actually reduced such that no warpage, which could spread laterally, is generated. For example, plastic microspheres in a rubber compound, or a microporous cellular structure having enclosed gas chambers (foam materials), may be used here. The respective materials are, in particular, polyurethanes, crosslinked polyethylenes, polypropylenes, nitrile butadiene rubber, neoprene, and ethylene propylene monomer rubber. The elastic modulus is mostly in the range of 1 MPa to 1000 MPa. For further details pertaining to the compressible layer, reference is made in particular to U.S. Pat. No. 6,019,042 and EP 2 070 717 A1, the disclosure of which constitutes a component of the present invention.

One or more compressible layers are customarily provided between the printing form or the sleeve and the printing cylinder. Conventionally, to this end a double-sided adhesive tape between the printing form or the sleeve and the printing cylinder can be used on the one hand, this having the disadvantage however that the adhesive tape, besides its damping effect, generates adhesion and complicates the removal of the printing form or the printing sleeve, or thereby leaves behind residue on the printing cylinder. On the other hand, corresponding adapters, which are arranged as separate elements between the printing form or the sleeve and the printing cylinder, may be conventionally used. These cause additional costs, and their introduction or removal requires an additional outlay.

It is thus advantageous to provide one compressible layer or a plurality of compressible layers as a component of the actual printing form. In this manner, the compressible layer or the compressible layers, respectively, can be mounted together with the printing form, for example by compressed air from the inside or by suction by means of a vacuum from the outside, on a printing cylinder and also be removed again without residue. Furthermore, a separate adapter can be dispensed with.

According to a further aspect of the invention, at least one layer has a magnetic or magnetizable material.

To this end, for example iron filings, metallic or magnetic particles, or a magnetic powder may have been introduced into the material of a layer of the printing form. This is advantageous, since the printing form can be retained on an underlayer, such as for example a printing cylinder, by means of a magnetic force in this manner. Here, adhesives are customarily used to date. However, the adhesives may macerate, that is modify their shape in particular with respect to their height and, on account of this, raise regions of the printing form. On account of this, depressions or non-image sites can be raised in such a manner that they unintentionally act as elevated printing elements or image sites and, in doing so, modify the printing template and render useless the print substrate, since another printed image is created in place of the one intended.

To this end, for example iron filings or a magnetic powder may be used in the material of a layer of the printing form. This layer having a magnetic or magnetizable material may here be the first layer, as an actual printing layer, a separate further layer, the essential object of which it is to receive the magnetic or magnetizable material, or also a further layer, such as a reinforcement layer or a compressible layer, which, in addition to its stabilizing or damping effect, additionally receives the magnetic or magnetizable material.

The magnetic or magnetizable properties of the printing form may also be used for expanding the printing form by magnetic forces which act in the radial direction R, to guide it in the expanded state over a printing cylinder or similar, and to then remove again the magnetic forces, such that the expansion of the printing form is repealed and the printing form contracts again, on account of which the printing form is securely positioned on the printing cylinder or similar. To this end, on the one hand, a magnetic force, which pulls the printing form toward the outside and thereby expands it, may be applied from the outside in the radial direction R. On the other hand, a repelling magnetic force, which repels the printing form and thereby expands it, may also be generated by the printing cylinder or similar.

The invention further relates to a printing cylinder for use in relief printing, in particular flexographic printing, having a printing form configured as a cylindrical layer structure which has at least a first layer including a vulcanizate based on at least one elastomer and a layer thickness, the first layer being extruded, wherein the printing form is at least in portions directly attached, in the radial direction R, to the surface of the printing cylinder.

The term “printing cylinder” is understood to mean a printing form which is made of a cylindrical body, on the surface of which, oriented in the radial direction R toward the outside, a printing template is provided. A printing cylinder may be made of, for example, a steel hollow core and a surface which is coated with copper. A printing cylinder may also be referred to as a printing mandrel.

It is advantageous in the use of a printing form according to the invention directly on a printing cylinder that reinforcement members and other further layers of the printing form, as they are conventional and customary, can be dispensed with. This leads to a simplification of manufacturing, handling, storage, etc. of the printing form, with corresponding cost savings, in particular in the manufacture.

The elastic printing form here may be widened, for example, by means of compressed air from the inside or by suction by means of a vacuum from the outside and, in this manner, mounted on the printing cylinder and also removed again from the latter. In this manner, adhesives, in order to avoid a relative movement between the lower side, or the inner side, of the printing form and the surface, or the outer side, of the printing cylinder, can be dispensed with. On account of dispensing with adhesives, material and time for the application of such means are saved, on account of which the costs and the outlay for the use of a printing form according to the invention are reduced for the user in the printing shop. Furthermore, the printing form according to the invention may be removed again without residue by means of compressed air from the inside, or by suction by means of a vacuum from the outside, from the surface of the printing cylinder.

The elasticity of the printing form according to the invention here is to be provided such that, for example by means of a corresponding selection of materials or a mixture of materials of at least the elastomeric components of the first layer, on the one hand an expansion of the printing form is possible to the extent that the printing form can be mounted (for example pushed onto) a printing cylinder, and on the other hand the printing form is securely retained on the printing cylinder. Securely retained is understood to mean that the printing form does not carry out any relative movement in relation to the printing cylinder, even under the influence of torsional forces and centrifugal forces. Centrifugal forces may arise, for example on account of the rotation of the printing cylinder. Torsional forces may be generated, for example as a result of mechanical machining, such as for example grinding, finishing, polishing and similar of the surface of the printing form for developing the printing form (printing relief).

Alternatively, the printing form according to the invention, once it has been widened and mounted on the printing cylinder by means of compressed air from the inside, or by suction by means of a vacuum from the outside, may also be fixed on the surface of the printing cylinder by means of adhesives. In this manner, the printing form can be secured against relative movements on the printing cylinder by means of a combination of the elasticity of its material and the adhesive effect of the adhesive. The adhesive effect of the adhesive here is preferably to be assessed and provided such that both a secure fixation in relation to impinging centrifugal forces and/or torsional forces takes place, and the printing form can be removed from the printing cylinder again—with as little residue as possible—by means of compressed air from the inside or by suction by means of a vacuum from the outside.

Furthermore, a magnetic or magnetizable material may also be provided in the material of the printing form. In this case, a secure fixation of the printing form according to the invention in relation to the printing cylinder may also take place, additionally or alternatively to the previously described possibilities, by means of magnetic attraction forces.

A secure retention between the printing form and the printing cylinder may also be caused in that the printing form has a layer which is, in the radial direction R, arranged below the printing layer and can be induced to contract, that is to shrink. To this end, a shrink film, which contracts, that is shrinks, when heated, may be used. Such materials are known from, for example, shrink tubing, which is pulled over electrical connection points and is shrunk by means of hot air, for example by a hot-air gun, in order to seal the electrical connection points. A further layer, for example a reinforcement layer, of the printing form is preferably configured as a shrinkable layer.

A secure retention may also be generated by a woven or knitted fabric or by a braid which is provided for example as a reinforcement layer in the printing form. For this purpose, the woven or knitted fabric, or braid, may have an interlaced profile, such that, for example by being pushed together in the axial direction A, the printing form expands in the radial direction R and the woven or knitted fabric, or braid, is loosened on account thereof. In this state, the printing form can be pushed onto for example a printing cylinder or similar. Subsequently, pushing together can be repealed, on account of which the printing form expands again in the axial direction A and the interlaced woven or knitted fabric, or braid, is tensioned such that the printing form is securely retained on the printing cylinder or similar. This principle of an interlaced woven or knitted fabric, or braid, is also known as “finger trap”. Here, the hysteresis tension of the interlaced woven or knitted fabric, or braid, is utilized and clamping in relation to the printing cylinder is achieved in the state in which the fabric or braid is not pushed together.

Furthermore, a layer or coating having an anti-slip property may be configured on the inner side, in the radial direction R, of the printing form, in order to establish a secure retention on account thereof. This may be achieved by material properties of this layer or coating, as also by its surface texture.

The invention also relates to a sleeve for use in relief printing, in particular flexographic printing, having a reinforcement member, in particular a dimensionally stable reinforcement member, and a printing form configured as a cylindrical layer structure which has at least a first layer including a vulcanizate based on at least one elastomer and a layer thickness, the first layer being extruded.

The term “sleeve” is understood to mean a printing sleeve, a sleeve or a carrier sleeve, as it is used in printing technology in order to mount a printing form, in particular a printing layer, on a printing cylinder. This term is understood to mean the interchangeable outer shell in intaglio printing cylinders or flexographic printing cylinders.

It is advantageous in this construction of a sleeve that the printing form according to the invention can be used in combination with a strength carrier, in particular a dimensionally stable reinforcement member, in order to form a sleeve which can be used like the customarily manufactured sleeves to date. In this manner, the printing form manufactured and constructed according to the invention is more simply, more rapidly and more cost-effectively produced than is customary to date; however, the sleeve product shipped to the customer has, to him, no differences of any kind, or only insignificant differences, and has the required quality. On account of this the acceptance of the sleeve product with users can also be enhanced, and the cost saving of manufacturing according to the invention, or construction according to the invention, can be utilized by the user.

The invention also relates to a method for making a printing form configured as a cylindrical layer structure which has at least a first layer including a vulcanizate based on at least one elastomer and a layer thickness, the first layer being extruded, the method for making having at least the following steps:

in a first step, extruding a first layer of the printing form, wherein the first layer has a vulcanizate based on at least one elastomer, and

in a further step, applying the printing form to a cylindrical body.

This method relates to the manufacturing of a printing form, such as shipped to a printing shop, an engraver's or similar, in order to configure on this printing form a printing template and then to use the latter as a printing template for printing.

To this end, in a first step, the printing form is extruded in the form of an at least one first layer. The printing form is then, in a subsequent step, mounted on a cylindrical body, which may be a printing cylinder or also a mount for a further machining step. The printing form may also be mounted on a reinforcement member, preferably a dimensionally stable reinforcement member, and in this form mounted on a printing cylinder or, for a further machining step, on a mount.

The printing form here is preferably mounted on the printing cylinder in that the printing form is expanded from the inside by means of compressed air or from the outside by means of a vacuum and in this state mounted over the reinforcement member.

According to the invention it may also be part of this first step that extruding the at least first layer takes place on a reinforcement layer, for example a knitted fabric, braid or warp knit. To this end, making of the reinforcement layer may take place in a corresponding production installation, for example on a mandrel or similar, onto which reinforcement layer the at least first layer is subsequently extruded.

According to one aspect of the invention, the method for manufacturing a printing form has the subsequent step: reducing the layer thickness of the first layer in the printing form.

This method step is based on the findings that a printing form having a first extruded layer generally does not yet have the layer thickness and possibly also not the surface texture which a printing form must have in order to be able to be used in printing technology. In particular in a cylindrical printing form, its true running is an important quality criterion. Rather, the printing form according to the invention after extruding has, in the radial direction R, an at least slight overdimensioning, which is method-related or desired, that is has a larger layer thickness than the finished printing form.

According to the invention, in a corresponding method step for manufacturing a printing form, this overdimensioning can be removed, for example, by a cutting removal, such as turning or grinding. The overdimensioning is preferably removed by grinding in the radial direction R, since on account of this a very fine setting of the desired layer thickness and simultaneously a comparatively uniform surface quality can be achieved.

To this end it is advantageous to mount the extruded printing form on a cylindrical mount, for example via compressed air from the inside or via a vacuum from the outside, to let the printing form rotate on this cylindrical mount in a corresponding production installation, and to for example turn away or grind away the excessive material here.

Additionally or alternatively, the surface texture of the printing form may also be machined in such a step, for example by grinding, polishing, or finishing, preferably by grinding. These two method steps may preferably take place simultaneously and in the same production installation, the corresponding tools being arranged such that the rotating printing form to be machined is first machined with respect to its layer thickness and subsequently, if applicable, with respect to its surface quality.

Grinding is particularly preferably used here for both setting the layer thickness and also for manufacturing the desired surface texture, since in this manner two method steps can be combined by means of one tool, that is grinding simultaneously carries out two method steps on the same point of the printing form. On account of this the outlay in manufacturing a printing form can be reduced, and the quality of the printing form can be enhanced.

Particularly preferably, a method according to the invention for manufacturing a printing form configured as a cylindrical layer structure which has at least a first layer including a vulcanizate based on at least one elastomer and a layer thickness, the first layer being extruded, the method can includes the following steps:

In a first step, at least a first layer of the printing form can be manufactured by extruding, wherein the first layer has a vulcanizate based on at least one elastomer. Extruding the first layer may preferably take place on a sub-layer, for example a mandrel such as customarily used for the manufacture of tubes. Particularly preferable here is extruding the first layer on a mandrel, on which previously a reinforcement layer in the form of a knitted fabric, braid or warp knit has been mounted.

In a further step, the first layer can be removed from the mandrel, if applicable, for example via compressed air from the inside or by suction from the outside, and thereafter cut to the desired length in the axial direction A, as is required for the printing form.

In a further step, the printing form can be mounted on a cylindrical body. The latter is preferably a mount as an auxiliary means in order to be able to handle the printing form in the further manufacturing steps. This may likewise take place, for example, by means of compressed air from the inside or by suction from the outside.

In a further step, the printing form can be clamped, via the mount, in a production installation in which the printing form can be rotated. In this production installation, preferably via grinding, the desired layer thickness and thus the true running of the cylindrical printing form can take place, on the one hand, by removal of excess material in the radial direction R. On the other hand, by grinding, a desired surface structure of the first layer, as a printing layer of the printing form, can be simultaneously set.

In a further step, the printing template (deep engraving) can be carved out on the printing layer of the printing form. This may take place by removal of the depressions or non-image sites of the printing template, such that merely the printing elements or the image sites of the printing template, elevated in the radial direction R, remain after removal, in order to transfer the printing ink onto the print substrate. Preferably, removal takes place by means of laser cutting.

It is preferable here if the step of grinding and of removal take place in the same production installation. This has the advantage that the mount together with the printing form does not require renewed clamping or even a changeover of the printing form from one mount to another between the manufacturing steps. On account of this, the expenditure of time is reduced on the one hand. On the other hand, fewer mounts are required. Both matters reduce the manufacturing outlay and also the logistical outlay and, on account thereof, the costs.

The printing form can furthermore be produced with tighter tolerances, on account of which the quality of the printing form is enhanced. The reason for this lies in the fact that in every changeover of the mount together with the printing form between different production installations, in particular involving removal and renewed mounting of the printing form onto different mounts, a new positioning of the printing form takes place in relation to the respective machining tool, something that always contains an element of unreliability in positioning. In contrast, if a plurality of manufacturing steps are carried out on the same production installation, this element of unreliability in positioning can be avoided.

In a further step, the completed printing form together with the mount can be removed from the production installation, and the printing form can be removed from the mount, for example by means of compressed air from the inside or by suction from the outside. The completed printing form may then be mounted on a printing cylinder, for example by means of compressed air from the inside or by suction from the outside, and used for printing.

The invention further relates to a device for machining a printing form configured as a cylindrical layer structure which has at least a first layer including a vulcanizate based on at least one elastomer and a layer thickness, the first layer being extruded. The device has at least one first machining tool for reducing the layer thickness of the first layer of the printing form, preferably a grinding tool. The device further has a further machining tool for configuring the printing template of the first layer of the printing form, preferably a laser for the removal of material of the first layer of the printing form.

This device relates to the concept that a printing form according to the invention can be further machined, for example the printing template can be mounted on the printing form, in a simpler and more cost-effective manner than is customary to date. In this manner, according to the invention, the extruded printing form, which, in the radial direction R, has an at least slight overdimensioning of the printing layer, which is method-related or desired, and generally an uneven surface, which is method-related, can be trued for running, in the form of the desired layer thickness and surface texture, on the same device in which the development of the printing template takes place.

As a device of this type, for example a production installation can be considered which has a mount that is comparable to a printing cylinder, on which a printing form together with, or even without, a reinforcement member can be mounted for machining here. To this end, the extruded printing form can be rendered to the desired layer thickness for example via grinding or turning. For configuring the desired surface texture, the printing form may, for example, be finished, polished or ground. These two operations can take place in the same production installation by two different machining tools. It is, however, preferable to carry out these two operations with the same machining tool, which is preferably a grinding tool.

In this production installation, the establishment of the printing template by removal of the depressions or non-image sites, for example via a laser, milling tool or similar, preferably via a laser, may according to the invention take place in a subsequent step or simultaneously with the afore-described machining. Accordingly, it is particularly advantageous to combine these method steps in one production installation in order to save costs and time. For example, in this manner an extruded printing form can rotate in the production installation and be rendered to the desired layer thickness and the desired surface texture by a first machining tool, such as preferably a grinding tool which is preferably adjustable in the radial direction R, and the printing template can be carved out by removal of the corresponding depressions or non-image sites of the printing template by a further machining tool of the same production installation, such as preferably a laser, preferably a carbon dioxide laser, a fiber laser or a diode laser.

The invention also relates to the use of a tube, which has a vulcanizate based on at least one elastomer, as a printing form for relief printing, in particular flexographic printing.

This aspect of the invention is based on the concept that for the manufacturing of a printing form, in particular for the manufacturing of the printing layer of a printing form, which has a vulcanizate based on at least one elastomer, a corresponding tube can be used in the simplest case. Therefore, separate manufacturing methods can be dispensed with, and a corresponding tube can be manufactured via the methods which are customary herefor. This tube may then be used as a printing form by being directly fitted on a printing cylinder and used as a printing form.

The tube, as a printing form, may also be fitted on a reinforcement member, in particular a dimensionally stable reinforcement member, and used in this combination as a sleeve. The sleeve thus created can then be subsequently handled and further processed like a sleeve manufactured as is customary to date, such that no re-adjustment in relation to previously establishing and using a printing template takes place for the user. However, significant costs can be saved by manufacturing the sleeve according to the invention, without deterioration of the quality of the sleeve.

### BRIEF DESCRIPTION OF THE DRAWINGS

The invention will now be described with reference to the drawings wherein:

FIG. 1A is a perspective schematic view of a cylindrical layer structure, according to the invention, in the form of a printing form, according to a first exemplary embodiment;

FIG. 1B shows a half-section through the perspective schematic view of FIG. 1A;

FIG. 2A is a perspective schematic view of a cylindrical layer structure, according to the invention, in the form of a printing form, according to a second exemplary embodiment;

FIG. 2B shows a half-section through the perspective schematic view of FIG. 2A;

FIG. 3A is a perspective schematic view of a cylindrical layer structure, according to the invention, in the form of a printing form, according to a third exemplary embodiment;

FIG. 3B shows a half-section through the perspective schematic view of FIG. 3A;

FIG. 4A is a perspective schematic view of a cylindrical layer structure, according to the invention, in the form of a printing form, according to the first exemplary embodiment, which is arranged on a printing cylinder;

FIG. 4B shows a half-section through the perspective schematic view of FIG. 4A;

FIG. 5A shows a perspective schematic view of a cylindrical layer structure, according to the invention, in the form of a printing form, according to the first exemplary embodiment, which is arranged on a reinforcement member;

FIG. 5B shows a half-section through the perspective schematic view of FIG. 5A;

FIG. 6A shows a perspective schematic view of a production installation for machining a cylindrical layer structure, according to the invention, in the form of a printing form, according to the first exemplary embodiment, which is arranged on a mount;

FIG. 6B shows a half-section through the perspective schematic view of FIG. 6A;

FIG. 7A shows a perspective schematic view of a preferred production installation, according to the invention, for machining a cylindrical layer structure, according to the invention, in the form of a printing form, according to the first exemplary embodiment, which is arranged on a mount; and,

FIG. 7B shows a half-section through the perspective schematic view of FIG. 7A.

### DESCRIPTION OF THE PREFERRED EMBODIMENTS OF THE INVENTION

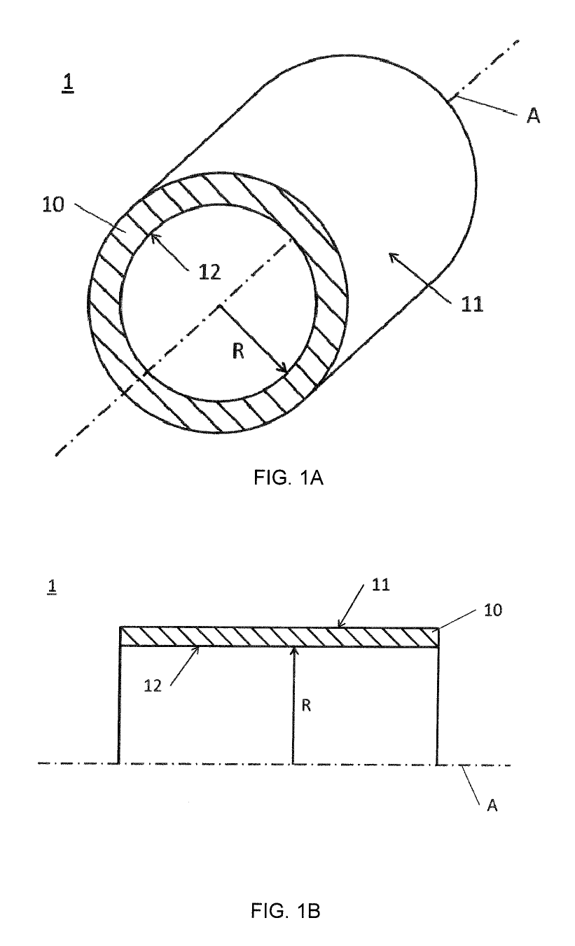

FIG. 1A shows a perspective schematic view of a cylindrical layer structure 1, according to the invention, in the form of a printing form 1, according to a first exemplary embodiment. FIG. 1B shows a half-section through the perspective schematic view of FIG. 1A.

In this first exemplary embodiment, the printing form 1 is of single-layered construction and has merely one first layer 10. The first layer 10 constitutes the printing layer 10 of the printing form 1 and may be formed by a tube 1. The printing layer 10, in the radial direction R, which is oriented perpendicularly to the axial longitudinal direction A of the printing form 1, has in an outward orientation a surface 11 (outer surface 11), which constitutes the printing surface 11 of the printing form 1. For establishing a printing template (a printing relief), the printing elements or image sites are carved out on the printing layer 10.

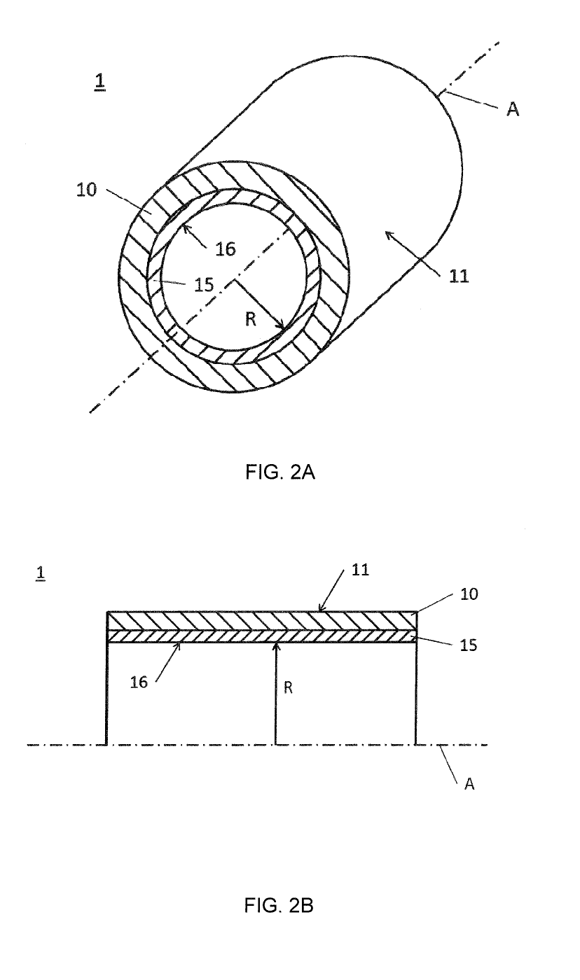

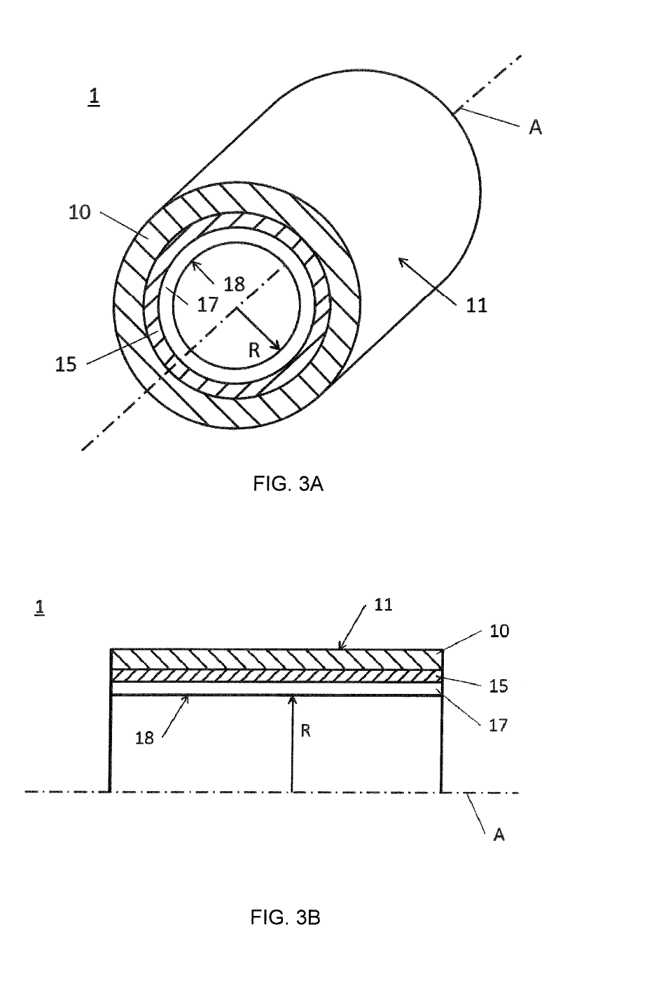

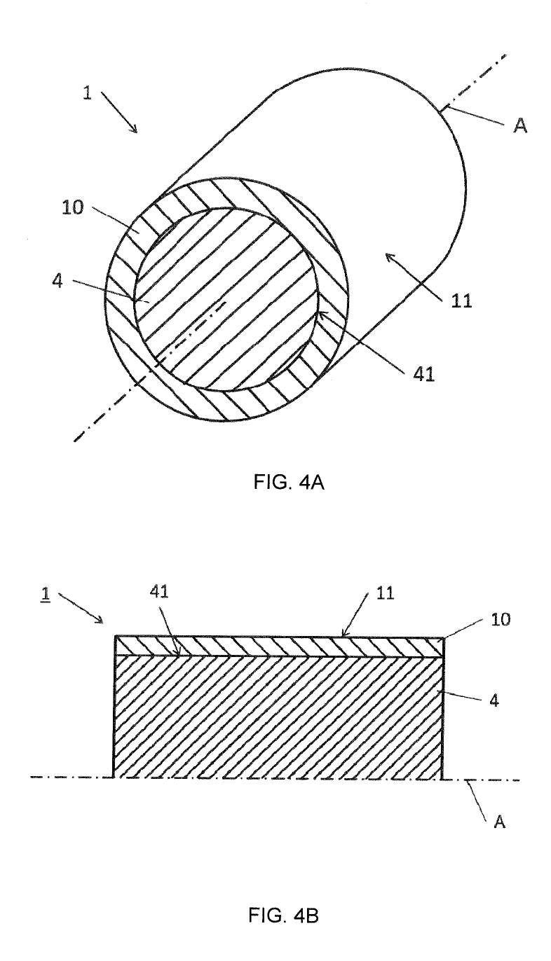

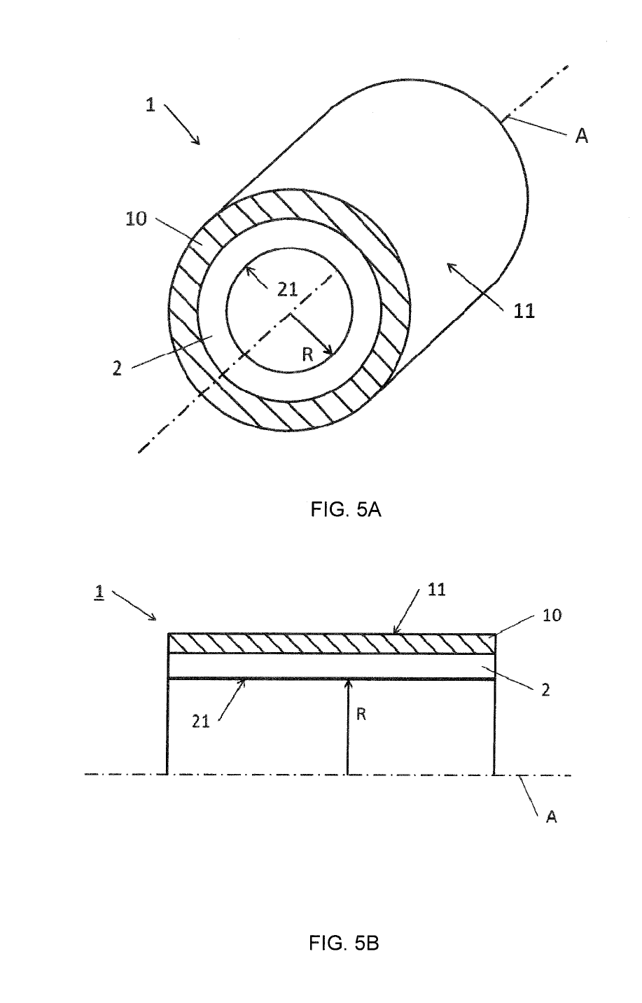

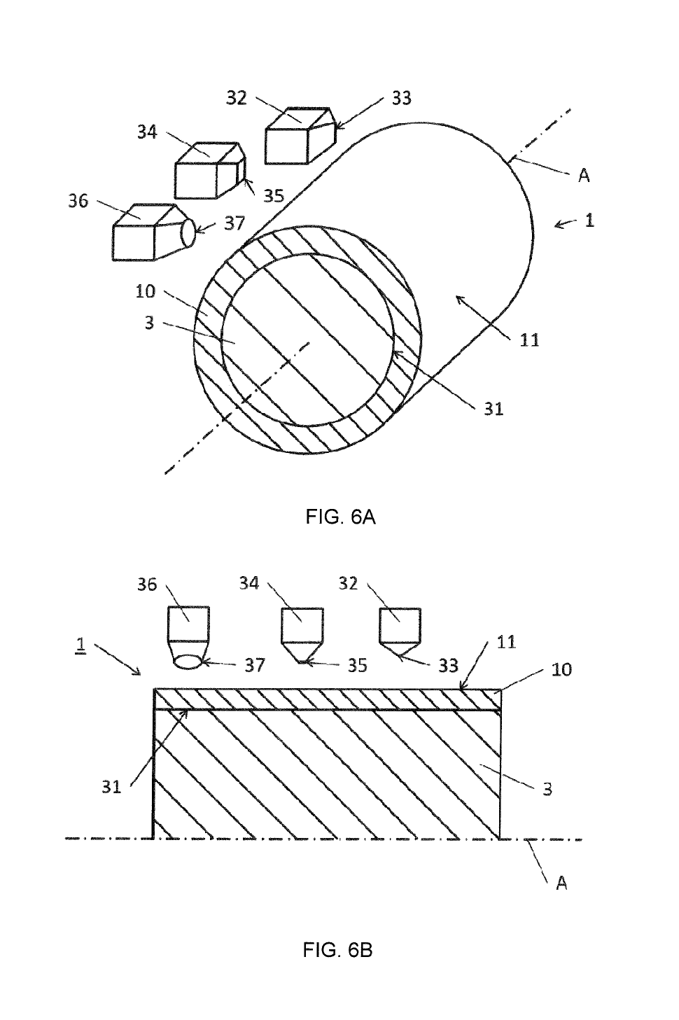

The printing layer 10 further has, in the radial direction R, in an inward orientation a surface 12 (inner surface 12), which constitutes the contact face 12 of the printing layer 10. With this contact face 12, the printing layer 10 can bear on a layer, or also bodies, arranged below the printing layer 10 in the radial direction R. In the case of a multilayered configuration, according to, for example, the second or third exemplary embodiment of the present invention, these may be a further layer (15, 17) (cf. FIGS. 2A to 3B). In the first exemplary embodiment, however, the printing form 1 is constructed exclusively from the printing layer 10. Accordingly, the printing form 1, with the contact face 12 of the printing layer 10, can bear directly on a printing cylinder 4 (cf. FIGS. 4A and 4B), a mount for machining (cf. FIGS. 6A and 6B), or a reinforcement member 2, in particular a dimensionally stable reinforcement member 2 (cf. FIGS. 5A and 5B).

FIG. 2A shows a perspective schematic view of a cylindrical layer structure 1, according to the invention, in the form of a printing form 1, according to a second exemplary embodiment. FIG. 2B shows a half-section through the perspective schematic view of FIG. 2A.

In this second exemplary embodiment, the printing form 1 is of multilayered construction and, in this sequence from the outside to the inside in the radial direction R, has a first layer 10 as the printing layer 10 and a further layer 15 as the reinforcement layer 15. The contact face 12 of the printing layer 10 here, in the radial direction R, bears against the outer face of the reinforcement layer 15. The inner surface 16 of the reinforcement layer 15, in the radial direction R, is oriented toward the inside and, in this exemplary embodiment, constitutes the contact face 16 with which the printing form 1 can bear on a printing cylinder 4 (cf. FIGS. 4A and 4B), a mount for machining (cf. FIGS. 6A and 6B), or a reinforcement member 2, in particular a dimensionally stable reinforcement member 2 (cf. FIGS. 5A and 5B).

The reinforcement layer 15 may, for example, have a knitted fabric, braid or warp knit, and may be configured as a separate layer, as illustrated in FIGS. 2A and 2B, or also as a component of the printing layer 10. The reinforcement layer 15 here serves to enhance the stability of the printing form 1 without, however, canceling the latter's elastic properties. In this manner, the reinforcement layer 15, as a component of the printing form 1, is not to be confused with a reinforcement member 2, in particular a dimensionally stable reinforcement member 2, onto which, being a separate element, the printing form 1 may be fitted, if applicable (cf. FIGS. 5A and 5B).

FIG. 3A shows a perspective schematic view of a cylindrical layer structure 1, according to the invention, in the form of a printing form 1, according to a third exemplary embodiment. FIG. 3B shows a half-section through the perspective schematic view of FIG. 3A.

In this third exemplary embodiment, the printing form 1 is of multilayered construction and, in this sequence from the outside to the inside in the radial direction R, has a first layer 10 as the printing layer 10, a further layer 15 as the reinforcement layer 15, and a further layer as the compressible layer 17 (compression layer 17). The contact face 12 of the printing layer 10 here, in the radial direction R, bears against the outer face of the reinforcement layer 15. The contact face 16 of the reinforcement layer 15, in the radial direction R, bears against the outer face of the compressible layer 17. The inner surface 18 of the compressible layer 17, in the radial direction R, is oriented toward the inside and, in this exemplary embodiment, constitutes the contact face 18 with which the printing form 1 can bear on a printing cylinder 4 (cf. FIGS. 4A and 4B), a mount for machining (cf. FIGS. 6A and 6B), or a reinforcement member 2, in particular a dimensionally stable reinforcement member 2 (cf. FIGS. 5A and 5B).

The compressible layer 17 may, for example, have microspheres made from plastic in a rubber compound, or a microporous cellular structure having enclosed gas chambers (foam materials), in order to generate a compressible effect.

Alternatively to the sequence illustrated in FIGS. 3A and 3B, the reinforcement layer 15 and the compressible layer 17 may also be provided in the reverse sequence, in the radial direction R, within the printing layer 10.

Furthermore, in each of the afore-described exemplary embodiments, a magnetic or magnetizable material may be provided in the material of the printing layer 10, but also in the materials of the reinforcement layer 15 and/or the compressible layer 17, in order for example to let the printing form 1 adhere via magnetic forces on a subsurface, for example a printing cylinder 4 (cf. FIGS. 4A and 4B), a mount for machining (cf. FIGS. 6A and 6B), or a reinforcement member 2, in particular a dimensionally stable reinforcement member 2 (cf. FIGS. 5A and 5B).

FIG. 4A shows a perspective schematic view of a cylindrical layer structure 1, according to the invention, in the form of a printing form 1, according to the first exemplary embodiment, which is arranged on a printing cylinder 4. FIG. 4B shows a half-section through the perspective schematic view of FIG. 4A. The reference signs of the printing form 1 correspond to those of FIGS. 1A and 1B. The printing cylinder 4 has a surface 41, which, in the radial direction R, is oriented toward the outside, and on which the printing form 1 directly bears with the contact face 12 of its printing layer 10. In this manner, according to the invention, the use of a reinforcement member 2, in particular a dimensionally stable reinforcement member 2, can be dispensed with, in order to manufacture a printing form 1 and to subsequently use it on a printing cylinder 4.

FIGS. 4A and 4B show, in an exemplary manner for the printing form 1 of the first exemplary embodiment, how, according to the invention, a printing form 1 can be provided directly on a printing cylinder 4. Alternatively thereto, a printing form 1 according to the second or third exemplary embodiment, or according to a further embodiment, may also be used. In this case, the printing form 1 bears on the surface 41 of the printing cylinder 4 with the contact surface 16 of the reinforcement layer 15, or with the contact surface 18 of the compressible layer 17.

FIG. 5A shows a perspective schematic view of a cylindrical layer structure 1 in the form of a printing form 1, according to the invention, which, according to the first exemplary embodiment, is arranged on a reinforcement member 2. FIG. 5B shows a half-section through the perspective schematic view of FIG. 5A. the reference signs of the printing form 1 correspond to those of FIGS. 1A and 1B. The reinforcement member 2 has a surface 21 which, in the radial direction R, is oriented toward the outside, and on which the printing form 1 bears directly with the contact face 12 of its printing layer 10. The combination of the printing form 1 and the reinforcement member 2 may be described as a sleeve, printing sleeve, or also carrier sleeve.

This contact may be established here in that, for example, the printing form 1 is expanded by means of compressed air from the inside or by suction by means of vacuum from the outside, and the reinforcement member 2 is inserted into the expanded printing form 1. In the event that the compressed air or the vacuum is then removed, the elastic material of the printing form 1 contracts again, and the printing form 1 then, without being permanently connected to it, bears against the reinforcement member 2, that is without being connected to the reinforcement member in such a manner that it could only be removed again from the reinforcement member by destructive means.

FIGS. 5A and 5B show, in an exemplary manner for the printing form 1 of the first exemplary embodiment, how, according to the invention, a printing form 1 can be provided directly on a reinforcement member 2. Alternatively thereto, a printing form 1 according to the second or third exemplary embodiment, or according to a further configuration, may also be used. In this case, the printing form 1 bears on the surface 21 of the reinforcement member 2 with the contact surface 16 of the reinforcement layer 15, or with the contact surface 18 of the compressible layer 17.

FIG. 6A shows a perspective schematic view of a production installation, according to the invention, for machining a cylindrical layer structure 1, according to the invention, in the form of a printing form 1, according to the first exemplary embodiment, which is arranged on a mount 3. FIG. 6B shows a half-section through the perspective schematic view of FIG. 6A. The reference signs of the printing form 1 correspond to those of FIGS. 1A and 1B. The mount 3 has a surface 31 which, in the radial direction R, is oriented toward the outside, and on which the printing form 1 bears directly with the contact face 12 of its printing layer 10.

This contact may be established here in that, for example, the printing form 1 is expanded by means of compressed air from the inside or by suction by means of a vacuum from the outside, and the mount 3 is inserted into the expanded printing form 1. In the event that the compressed air or the vacuum is then removed, the elastic material of the printing form 1 contracts again, and the printing form 1 then, without being permanently connected to it, bears against the mount 3, that is in such a manner that it could only be removed again from the mount 3 by destructive means.

The mount 3 together with the printing form 1 can be received, for example, in a production installation (cutting machine) and rotated there about the longitudinal axis A of the printing form 1, in order to machine the surface 11 of the printing layer 10. This may take place, for example, via a first machining tool 32, which is provided for the layer removal of the printing layer 10. To this end, for example, a cutting tool 33, which is fixedly provided in the machining tool 32, can be used, the cutting tool 33 of the machining tool 32 being oriented and being able to be positioned in the radial direction R by the machining tool 32 in relation to the surface 11 of the printing layer 10 such that the cutting edge of the cutting tool 33 engages with the material of the printing layer 10 and, in a cutting manner, by means of rotating the mount 3 together with the printing form 1, in a turning process removes the printing layer 10 up to the desired layer thickness. Alternatively thereto, other processes, such as cutting, grinding, blasting (water blasting, sand blasting) and similar may be used, a grinding process being preferable.

In the event that, prior to the configuration of the printing template of the printing layer 10, the creation of desired surface quality of the surface 11 of the printing layer 10 is required or desired, then this may take place, on the one hand, in that the first machining tool 32 is used therefor by exchanging the cutting tool 33. To this end, for example, processes such as grinding, polishing, finishing and similar may be used. In this manner it is possible, for example, in a first step to manufacture the desired layer thickness of the printing layer 10 in the production installation with the first machining tool via a first cutting tool 33, to exchange the cutting tool 33, and, in a second machining step, to manufacture the desired surface quality of the surface 11 of the printing layer 10 in the production installation with the first machining tool 32, for example via a grinding tool 35.

On the other hand, two machining tools (32, 34), which are arranged behind one another in the production installation in the sequence of the machining steps, may simultaneously carry out these machining steps, parallel to one another, at different points of the printing form 1. To this end, the production installation may have a second machining tool 34, having, for example, a grinding tool 35.

Finally, via a third machining tool 36, the configuration of the printing template of the printing layer 10 can take place. To this end, for example a laser 37, or also a milling tool 37, can be used in order to carve out the printing elements or the image sites of the printing template by removal of the depressions or non-image sites, a laser 37 being preferable. The third machining tool 36 here can be arranged in the production installation such that it is fixedly and also spatially and temporally arranged in relation to the first machining tool 32 and the second machining tool 34 such that the three machining steps can also be carried out simultaneously, parallel to one another, at different points of the printing form 1. The third machining tool 36, as also the first machining tool 32 and the second machining tool 34, here may be provided so as to be positionable in the radial direction R in relation to the printing form 1.

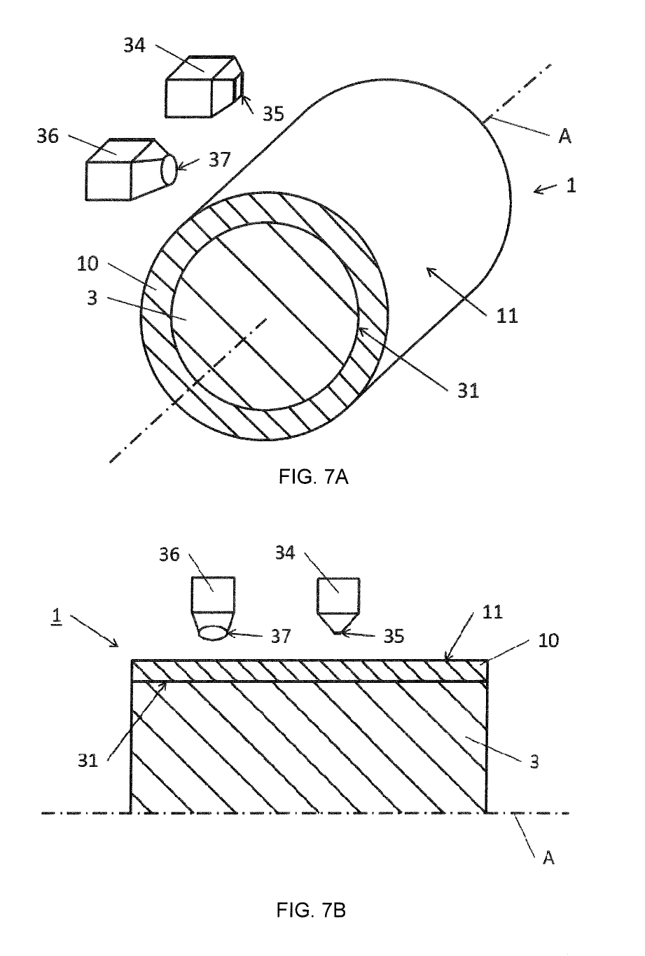

FIG. 7A shows a perspective schematic view of a preferred production installation, according to the invention, for machining a cylindrical layer structure 1, according to the invention, in the form of a printing form 1, according to the first exemplary embodiment, which is arranged on a mount 3. FIG. 7B shows a half-section through the perspective schematic view of FIG. 7A. The reference signs of the printing form 1 correspond to those of FIGS. 1A and 1B. The reference signs of the production installation correspond to those of FIGS. 6A and 6B.

In this preferred production installation according to the invention, the first machining tool 32 and the second machining tool 34 are combined with one another and collectively identified as the second machining tool 34 in that the second machining tool 34 is configured as a grinding tool 35 in such a manner that it can perform both the layer removal and also the machining of the surface texture. On account of this, one production step and the corresponding separate machining tool 32 can be economized.

It is understood that the foregoing description is that of the preferred embodiments of the invention and that various changes and modifications may be made thereto without departing from the spirit and scope of the invention as defined in the appended claims.

### LIST OF REFERENCE SIGNS

### Part of the Description

A axial direction of the printing form 1 or of the reinforcement member 2
R radial direction of the printing form 1 or of the reinforcement member 2, perpendicular to the axial direction A
1 printing form (single-layered or multilayered cylindrical layer structure, tube)
10 first layer of the printing form 1, printing layer
11 outer surface of the first layer 10, printing surface of the printing form 1
12 inner surface of the first layer 10, contact face of the printing layer
15 further layer of the printing form 1, reinforcement layer
16 inner surface of the reinforcement layer 15, contact face of the reinforcement layer 15
17 further layer of the printing form 1, compressible layer, compression layer
18 inner surface of the compressible layer 17, contact face of the compressible layer 17
2 reinforcement member, in particular a dimensionally stable reinforcement member
3 mount for machining a printing form 1
31 inner surface of the mount 3, contact face of mount 3
33 first machining tool for layer removal of the printing layer 10
33 cutting tool of the first machining tool 32
34 second machining tool for manufacturing a desired surface quality of the surface 11 of the printing layer 10
35 grinding tool of the second machining tool 34
36 third machining tool for configuring the printing template of the printing layer 10
37 laser, or milling tool, of the third machining tool 36
4 printing cylinder
41 outer surface of the printing cylinder 4

What is claimed is:

1. A printing form for relief printing and configured as a cylindrical layer structure, the printing form comprising:
at least a first layer including a vulcanizate based on at least one elastomer; and,
said first layer being extruded.

2. The printing form of claim 1, wherein said printing form is configured for flexographic printing.

3. The printing form of claim 1 further comprising a further layer configured as a reinforcement layer.

4. The printing form of claim 1 further comprising a further layer configured as a compressible layer.

5. The printing form of claim 3 further comprising another further layer configured as a compressible layer.

6. The printing form of claim 1, wherein said first layer includes at least one of magnetic material and magnetizable material.

7. The printing form of claim 3, wherein at least one of said first layer and said reinforcement layer includes magnetic material and magnetizable material.

8. The printing form of claim 4, wherein at least one of said first layer and said compressible layer includes magnetic material and magnetizable material.

9. The printing form of claim 5, wherein at least one of said first layer, said reinforcement layer and said compressible layer includes magnetic material and magnetizable material.

10. A printing cylinder configured for relief printing and defining a radial direction (R) and a surface, the printing cylinder comprising:
a printing form configured as a cylindrical layer structure having at least a first layer including a vulcanizate based on at least one elastomer;
said first layer being extruded; and,
said printing form being applied in the radial direction at least in sections directly to said surface of said printing cylinder in the radial direction (R).

11. The printing cylinder of claim 10, wherein said printing form further has at least of one a compressible layer and a reinforcement layer.

12. A printing sleeve configured for relief printing comprising:
a reinforcement member;
a printing form configured as a cylindrical layer structure having at least a first layer including a vulcanizate based on at least one elastomer;
said first layer being extruded; and,
said printing form being at least in part directly applied/attached to said surface of said printing cylinder in the radial direction (R).

13. The printing sleeve of claim 12, wherein said printing form further has at least one a compressible layer and a reinforcement layer.

14. A method for making a printing form configured as a cylindrical layer structure, the method comprising the steps of:
extruding a first layer of a printing form having a vulcanizate based on at least one elastomer in a first step; and,
applying the printing form to a cylindrical body in a further step.

15. The method of claim 14 further comprising the step of reducing the layer thickness of the first layer of the printing form.

16. A printing form machining apparatus, wherein the printing form is configured as a cylindrical layer structure and has at least a first layer including a vulcanizate based on at least one elastomer and a layer thickness, the first layer being extruded, the printing form machining apparatus comprising:
a first machining tool configured to reduce the layer thickness of the first extruded layer; and,
a second machining tool to configure a printing template of the first layer of the printing form.

17. The printing form machining apparatus of claim 16, wherein said first machining tool is a grinding tool.

18. The printing form machining apparatus of claim 16, wherein said second machining tool is a laser configured to remove material from the first layer of the printing form.
